(19) United States
(12) Patent Application Publication
(10) Pub. No.: US 2021/0367186 A1
(43) Pub. Date: Nov. 25, 2021

(54) OLED DISPLAY PANEL AND MANUFACTURING METHOD

(71) Applicant: SHENZHEN CHINA STAR OPTOELECTRONICS SEMICONDUCTOR DISPLAY TECHNOLOGY CO., LTD., Shenzhen (CN)

(72) Inventor: Shuning ZHAO, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/616,984

(22) PCT Filed: Aug. 26, 2019
(86) PCT No.: PCT/CN2019/102543

§ 371 Date: Nov. 26, 2019

(30) Foreign Application Priority Data
Jun. 21, 2019 (CN) 201910543026.3

(51) Int. Cl. H01L 51/52; H01L 27/32; H01L 51/00; H01L 51/56

(52) U.S. Cl. CPC H01L 51/5228; H01L 27/322; H01L 27/3246; H01L 51/5284; H01L 2251/558; H01L 51/56; H01L 2227/323; H01L 2251/308; H01L 51/0024

(57) ABSTRACT

An organic light-emitting diode (OLED) display panel and a manufacturing method include an array substrate and a color film substrate, the array substrate includes a first substrate, a thin-film transistor (TFT) layer, an anode metal layer, a pixel defining layer, an OLED light-emitting layer, and a cathode metal layer, and the color film substrate includes a second substrate, a black matrix, a color filter layer, and a protective layer; wherein a portion of the protective layer opposite to the cathode metal layer includes a cathode auxiliary wiring layer, and the cathode auxiliary wiring layer contacts the cathode metal layer.

### FIELD OF INVENTION

The present invention is related to the display field, and specifically to an organic light-emitting diode (OLED) display panel and a manufacturing method.

### BACKGROUND OF INVENTION

At present, compared with liquid crystal display (LCD) devices, organic light-emitting diode (OLED) display devices having advantages of self-luminescence, fast responses, high brightness, and vivid color and is considered to be a next-generation display technology. Depending on a direction of emitted light, the OLED display devices can be classified into a bottom-emitting type (i.e., emitting downwards with respect to a substrate) and a top-emitting type (i.e., emitting upwards with respect to the substrate). In order to increase transmittance of the top-emitting type OLED devices, it is necessary to make cathodes as thin as possible, but the thinner the cathodes, the larger the sheet resistance, resulting in a severe voltage drop of the top-emitting type OLED devices. After a signal of the cathodes is applied to an edge of an OLED display panel, a voltage drop from the edge of the OLED display panel to a center of the OLED display panel is more obvious, further causing the OLED display panel to exhibit significant uneven illumination when emitting.

In summary, in current OLED display panels and manufacturing methods, because a thickness of a metal cathode layer in the OLED display panel is too thin, sheet resistance thereof is too high, and a voltage drop from an edge of the OLED display panel to a center of the OLED display panel is more obvious, further causing the OLED display panel to exhibit significant uneven illumination when emitting.

### SUMMARY OF INVENTION

In current OLED display panels and manufacturing methods, because a thickness of a metal cathode layer in the OLED display panel is too thin, sheet resistance thereof is too high, and a voltage drop from an edge of the OLED display panel to a center of the OLED display panel is more obvious, further causing the OLED display panel to exhibit significant uneven illumination when emitting.

The present invention provides an organic light-emitting diode (OLED) display panel and a manufacturing method, reducing sheet resistance in a metal cathode layer of the OLED display panel, and solving technical problems in current OLED display panels and manufacturing methods that sheet resistance thereof being too high caused by a too thin thickness of a metal cathode layer in the OLED display panel, a voltage drop from an edge of the OLED display panel to a center of the OLED display panel being more obvious, and the OLED display panel exhibiting significant uneven illumination when emitting.

In order to solve the problems, the present invention provides technical solutions as follows:

The present invention provides an organic light-emitting diode (OLED) display panel including an array substrate and a color film substrate disposed opposite to the array substrate, the array substrate including a first substrate, a thin-film transistor (TFT) layer, an anode metal layer, a pixel defining layer, an OLED light-emitting layer, and a cathode metal layer disposed from bottom to top, and the color film substrate including a second substrate, a black matrix, a color filter layer, and a protective layer;

wherein a portion of the protective layer opposite to the cathode metal layer includes a cathode auxiliary wiring layer, the cathode auxiliary wiring layer contacts the cathode metal layer, and a thickness of the cathode auxiliary wiring layer ranges from 300 to 5000 Å.

In the OLED display panel provided by an embodiment of the present invention, a material of the cathode auxiliary wiring layer is selected from the group consisting of indium tin oxide (ITO), indium zinc oxide (IZO), and silver-magnesium alloy.

In the OLED display panel provided by an embodiment of the present invention, the cathode auxiliary wiring layer includes laminated an ITO layer, a silver metal layer, and an ITO layer.

In the OLED display panel provided by an embodiment of the present invention, the color filter layer includes a red resist, a green resist, and a blue resist, the black matrix is disposed between any two of the red resist, the green resist, and the blue resist, and the black matrix is disposed opposite to the pixel defining layer.

The present invention further provides an organic light-emitting diode (OLED) display panel including an array substrate and a color film substrate disposed opposite to the array substrate, the array substrate including a first substrate, a thin-film transistor (TFT) layer, an anode metal layer, a pixel defining layer, an OLED light-emitting layer, and a cathode metal layer disposed from bottom to top, and the color film substrate including a second substrate, a black matrix, a color filter layer, and a protective layer;

wherein a portion of the protective layer opposite to the cathode metal layer includes a cathode auxiliary wiring layer, and the cathode auxiliary wiring layer contacts the cathode metal layer.

In the OLED display panel provided by an embodiment of the present invention, a material of the cathode auxiliary wiring layer is selected from the group consisting of indium tin oxide (ITO), indium zinc oxide (IZO), and silver-magnesium alloy.

In the OLED display panel provided by an embodiment of the present invention, the cathode auxiliary wiring layer includes laminated an ITO layer, a silver metal layer, and an ITO layer.

In the OLED display panel provided by an embodiment of the present invention, the color filter layer includes a red resist, a green resist, and a blue resist, the black matrix is disposed between any two of the red resist, the green resist, and the blue resist, and the black matrix is disposed opposite to the pixel defining layer.

The present invention further provides a manufacturing method of an organic light-emitting diode (OLED) display panel including the steps of:

S10, providing a first glass substrate, sequentially coating a black matrix and a color filter layer on a surface of the first glass substrate, and coating a protective layer on a surface of the color filter layer, wherein the black matrix is located between two neighboring color filter layers;

S20, depositing a cathode auxiliary wiring layer on a surface of the protective layer, and defining a cathode auxiliary wiring region by lithography to obtain a color film substrate;

S30, providing a second glass substrate, forming a thin-film transistor (TFT) layer on the second glass substrate, depositing an anode metal layer on the TFT layer, coating an organic photoresist on the anode metal layer to form a pixel defining layer, and sequentially preparing an OLED light-emitting layer and a cathode metal layer on a surface of the pixel defining layer and a surface of the anode metal layer to obtain an array substrate; and

S40, encapsulating the array substrate and the color film substrate, contacting the cathode auxiliary wiring layer with the cathode metal layer, and finally forming the OLED display panel.

In the manufacturing method of the OLED display panel provided by an embodiment of the present invention, in the step S10, the color filter layer includes a red resist, a green resist, and a blue resist, the black matrix is disposed between any two of the red resist, the green resist, and the blue resist, and the black matrix is disposed opposite to the pixel defining layer.

In the manufacturing method of the OLED display panel provided by an embodiment of the present invention, in the step S20, a thickness of the cathode auxiliary wiring layer ranges from 300 to 5000 Å.

In the manufacturing method of the OLED display panel provided by an embodiment of the present invention, in the step S20, a material of the cathode auxiliary wiring layer is selected from the group consisting of indium tin oxide (ITO), indium zinc oxide (IZO), and silver-magnesium alloy.

In the manufacturing method of the OLED display panel provided by an embodiment of the present invention, in the step S20, the cathode auxiliary wiring layer includes laminated an ITO layer, a silver metal layer, and an ITO layer.

Beneficial effects of the present invention: an organic light-emitting diode (OLED) display panel and a manufacturing method provided by the present invention add a cathode auxiliary wiring layer contacting a cathode metal layer of an array substrate on a color film substrate side, reduce a voltage drop of the cathode metal layer on a top-emitting type OLED device, thereby improve a display effect of the OLED display panel.

### DESCRIPTION OF DRAWINGS

In order to describe technical solutions in the present invention clearly, drawings to be used in the description of embodiments will be described briefly below. Apparently, drawings described below are only for some embodiments of the present invention, and other drawings may be obtained by those skilled in the art based on these drawings without creative efforts.

FIG. 1 is a sectional structural diagram of an organic light-emitting diode (OLED) display panel of the present invention.

FIG. 2 is a flowchart of a manufacturing method of the OLED display panel of the present invention.

FIGS. 3A to 3D are schematic diagrams of the manufacturing method of the OLED display panel according to FIG. 2.

### DETAILED DESCRIPTION

Examples are described below with reference to the appended drawings, and the drawings illustrate particular embodiments in which the present invention may be practiced. Directional terms mentioned in the present invention, such as upper, lower, front, rear, left, right, in, out, side, etc., only refer to directions in the accompanying drawings. Thus, the adoption of directional terms is used to describe and understand the present invention, but not to limit the present invention. In the drawings, units of similar structures are using the same numeral to represent.

The present invention is directed to current organic light-emitting diode (OLED) display panels and manufacturing methods. Because a thickness of a metal cathode layer in the OLED display panel is too thin, sheet resistance thereof is too high, and a voltage drop from an edge of the OLED display panel to a center of the OLED display panel is more obvious, further causing the OLED display panel to exhibit significant uneven illumination when emitting. The present invention can solve these disadvantages.

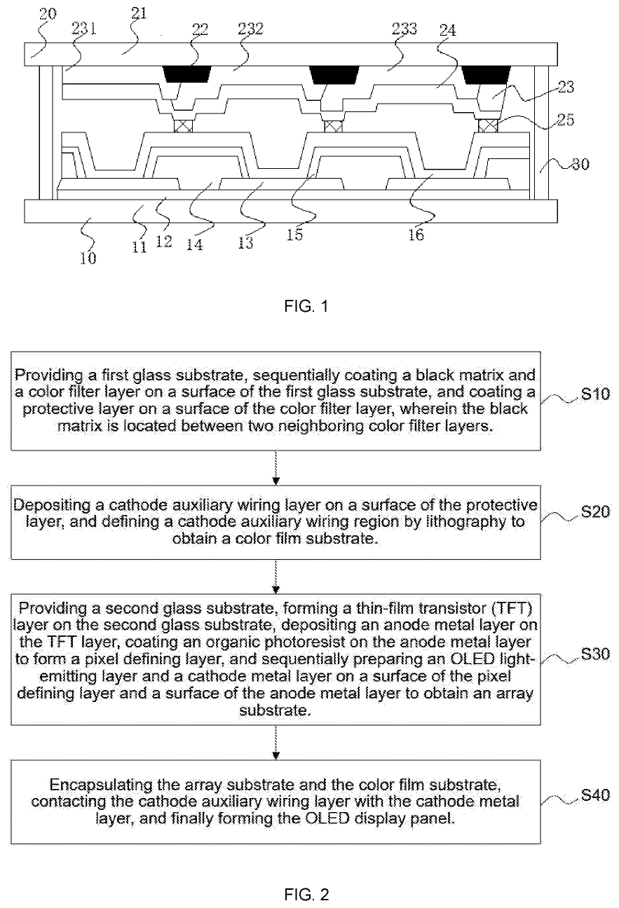

As shown in FIG. 1, FIG. 1 is a sectional structural diagram of an organic light-emitting diode (OLED) display panel of the present invention.

Specifically, the OLED display panel includes an array substrate 10 and a color film substrate 20 disposed opposite to the array substrate. The array substrate 10 includes a first substrate 11, a thin-film transistor (TFT) layer 12, an anode metal layer 13, a pixel defining layer 14, an OLED light-emitting layer 15, and a cathode metal layer 16 disposed from bottom to top. The color film substrate 20 includes a second substrate 21, a black matrix 22, a color filter layer 23, and a protective layer 24. The array substrate 10 and the color film substrate 20 are sealed by an encapsulant 30 to obtain the OLED display panel.

Wherein a portion of the protective layer 24 opposite to the cathode metal layer 25 includes a cathode auxiliary wiring layer 25, and the cathode auxiliary wiring layer 25 contacts the cathode metal layer. Preferably, the protective layer 24 can be made of a photosensitive material.

Specifically, a thickness of the cathode auxiliary wiring layer ranges from 300 to 5000 Å.

Preferably, a material of the cathode auxiliary wiring layer 25 is selected from the group consisting of indium tin oxide (ITO), indium zinc oxide (IZO), and silver-magnesium alloy. Preferably, the cathode auxiliary wiring layer 25 includes laminated an ITO layer, a silver metal layer, and an ITO layer.

Specifically, the color filter layer 23 includes a red resist 231, a green resist 232, and a blue resist 233, the black matrix 22 is disposed between any two of the red resist 231, the green resist 232, and the blue resist 233, and the black matrix 22 is disposed opposite to the pixel defining layer 14.

Specifically, a thickness of the black matrix 22 ranges from 5000 to 50000 Å. A thickness of the red resist 231, the green resist 232, and the blue resist 233 ranges from 5000 to 50000 Å. A thickness of the protective layer 24 ranges from 5000 to 50000 Å.

Specifically, a material of the anode metal layer 13 is ITO or IZO, and the anode metal layer 13 is preferably a laminated an ITO layer, a silver metal layer, and an ITO layer. A thickness of the anode metal layer 13 ranges from 100 to 3000 Å.

Specifically, the pixel defining layer 14 is an organic photoresist, and a thickness of the pixel defining layer 14 ranges from 5000 to 50000 Å.

Specifically, a material of the cathode metal layer 16 is a magnesium-silver alloy, aluminum, ITO or IZO, and a thickness of the cathode metal layer 16 ranges from 100 to 3000 Å.

An organic light-emitting diode (OLED) display panel provided by the present invention adds a cathode auxiliary wiring layer 25 contacting a cathode metal layer of an array substrate 10 on a color film substrate side 20, effectively reduce a voltage drop of the cathode metal layer 16, further improve the OLED display panel to exhibit uneven illumination when emitting.

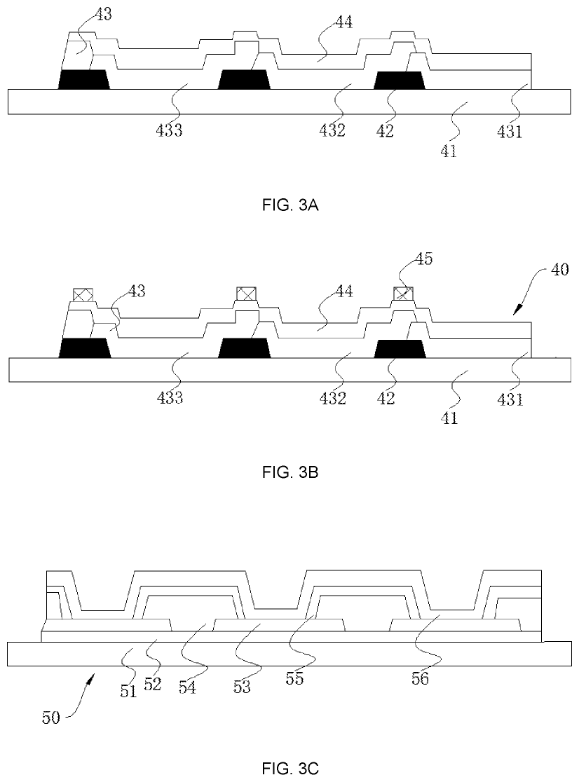

As shown in FIG. 2, FIG. 2 is a flowchart of a manufacturing method of an organic light-emitting diode (OLED) display panel of the present invention, the manufacturing method of the OLED display panel includes:

S10, providing a first glass substrate 41, sequentially coating a black matrix 42 and a color filter layer 43 on a surface of the first glass substrate 41, and coating a protective layer 44 on a surface of the color filter layer 43, wherein the black matrix 42 is located between two neighboring color filter layers 43.

Specifically, the step S10 further includes:

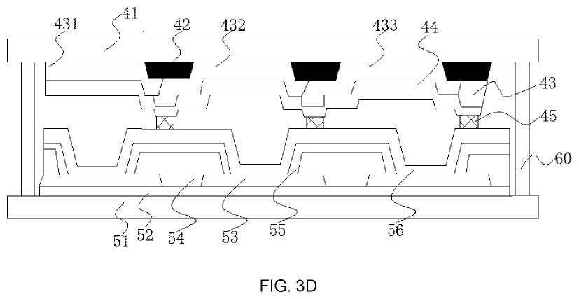

First, the first glass substrate 41 is provided, the black matrix 42 is deposited on the surface of the first glass substrate 41, a thickness of the black matrix 42 ranges from 5000 to 50000 Å, and a black matrix region is defined by lithography. Second, a red resist 431, a green resist 432, and a blue resist 433 are sequentially applied to the surface of the first glass substrate 41 to form the color filter layer 43, the black matrix 42 is disposed between any two of the red resist 431, the green resist 432, and the blue resist 433, and a thickness of the red resist 431, the green resist 432, and the blue resist 433 ranges from 5000 to 50000 Å. Third, the protective layer 44 is coated on the surface of the color filter layer 43, the protective layer 44 is used to protect the red resist 431, the green resist 432, and the blue resist 433, and a thickness of the protective layer 44 ranges from 5000 to 50000 Å. Preferably, the protective layer 44 can be made of a photosensitive material, as shown in FIG. 3A.

S20, depositing a cathode auxiliary wiring layer 45 on a surface of the protective layer 44, and defining a cathode auxiliary wiring region by lithography to obtain a color film substrate 40.

Specifically, the step S20 further includes:

The cathode auxiliary wiring layer 45 is deposited on the surface of the protective layer 44, and the cathode auxiliary wiring region is defined by lithography to obtain a color film substrate 40. Wherein a thickness of the cathode auxiliary wiring layer 45 ranges from 300 to 5000 Å. Preferably, a material of the cathode auxiliary wiring layer 45 is selected from the group consisting of indium tin oxide (ITO), indium zinc oxide (IZO), and silver-magnesium alloy. Preferably, the cathode auxiliary wiring layer 45 includes laminated an ITO layer, a silver metal layer, and an ITO layer, as shown in FIG. 3B.

S30, providing a second glass substrate 51, forming a thin-film transistor (TFT) layer 52 on the second glass substrate 51, depositing an anode metal layer 53 on the TFT layer 52, coating an organic photoresist on the anode metal layer 53 to form a pixel defining layer 54, and sequentially preparing an OLED light-emitting layer 55 and a cathode metal layer 56 on a surface of the pixel defining layer 54 and a surface of the anode metal layer 53 to obtain an array substrate 50.

Specifically, the step S30 further includes:

First, the second glass substrate 51 is provided, the TFT layer 52 is formed on the second glass substrate 51. Second, the anode metal layer 53 is deposited on the TFT layer 52, and anode region of the OLED display panel is defined by lithography, a material of the anode metal layer 53 is preferably ITO or IZO, the anode metal layer 53 is preferably a laminated an ITO layer, a silver metal layer, and an ITO layer, and a thickness of the anode metal layer 53 ranges from 100 to 3000 Å. Third, an organic photoresist is coated on the anode metal layer 53 to form the pixel defining layer 54, a light-emitting region is defined by lithography, and a thickness of the pixel defining layer 54 ranges from 5000 to 50000 Å. Fourth, an OLED light-emitting material is evaporated on the pixel defining layer 54 to form an OLED light-emitting layer 55. Last, cathode metal layer 56 is deposited on the OLED light-emitting layer 55 to obtain the array substrate 50, as shown in FIG. 3C.

S40, encapsulating the array substrate 50 and the color film substrate 40, contacting the cathode auxiliary wiring layer 45 with the cathode metal layer 56, and finally forming the OLED display panel.

Specifically, the step S40 further includes:

The array substrate 50 and the color film substrate 40 are sealed by an encapsulant 60, the cathode auxiliary wiring layer 45 is connected with the cathode metal layer 56, and the OLED display panel is formed finally, as shown in FIG. 3D.

Beneficial effects of the present invention: an organic light-emitting diode (OLED) display panel and a manufacturing method provided by the present invention add a cathode auxiliary wiring layer contacting a cathode metal layer of an array substrate on a color film substrate side, reduce a voltage drop of the cathode metal layer on a top-emitting type OLED device, thereby improve a display effect of the OLED display panel.

The foregoing are only preferred embodiments and are not for use in limiting the disclosure. Any modification, equivalent replacement, or improvement made without departing from the spirit and principles shall be covered by the protection scope.

What is claimed is:

1. An organic light-emitting diode (OLED) display panel, comprising:
an array substrate and a color film substrate disposed opposite to the array substrate, the array substrate comprising a first substrate, a thin-film transistor (TFT) layer, an anode metal layer, a pixel defining layer, an OLED light-emitting layer, and a cathode metal layer disposed from bottom to top, and the color film substrate comprising a second substrate, a black matrix, a color filter layer, and a protective layer;
wherein a portion of the protective layer opposite to the cathode metal layer comprises a cathode auxiliary wiring layer, the cathode auxiliary wiring layer contacts the cathode metal layer, and a thickness of the cathode auxiliary wiring layer ranges from 300 to 5000 Å.

2. The OLED display panel as claimed in claim 1, wherein a material of the cathode auxiliary wiring layer is selected from the group consisting of indium tin oxide (ITO), indium zinc oxide (IZO), and silver-magnesium alloy.

3. The OLED display panel as claimed in claim 1, wherein the cathode auxiliary wiring layer comprises laminated an ITO layer, a silver metal layer, and an ITO layer.

4. The OLED display panel as claimed in claim 1, wherein the color filter layer comprises a red resist, a green resist, and a blue resist, the black matrix is disposed between any two of the red resist, the green resist, and the blue resist, and the black matrix is disposed opposite to the pixel defining layer.

5. An organic light-emitting diode (OLED) display panel, comprising:
an array substrate and a color film substrate disposed opposite to the array substrate, the array substrate comprising a first substrate, a thin-film transistor (TFT) layer, an anode metal layer, a pixel defining layer, an OLED light-emitting layer, and a cathode metal layer disposed from bottom to top, and the color film substrate comprising a second substrate, a black matrix, a color filter layer, and a protective layer;
wherein a portion of the protective layer opposite to the cathode metal layer comprises a cathode auxiliary wiring layer, and the cathode auxiliary wiring layer contacts the cathode metal layer.

6. The OLED display panel as claimed in claim 5, wherein a material of the cathode auxiliary wiring layer is selected from the group consisting of indium tin oxide (ITO), indium zinc oxide (IZO), and silver-magnesium alloy.

7. The OLED display panel as claimed in claim 5, wherein the cathode auxiliary wiring layer comprises laminated an ITO layer, a silver metal layer, and an ITO layer.

8. The OLED display panel as claimed in claim 5, wherein the color filter layer comprises a red resist, a green resist, and a blue resist, the black matrix is disposed between any two of the red resist, the green resist, and the blue resist, and the black matrix is disposed opposite to the pixel defining layer.

9. A manufacturing method of an organic light-emitting diode (OLED) display panel, comprising the steps of:
S10, providing a first glass substrate, sequentially coating a black matrix and a color filter layer on a surface of the first glass substrate, and coating a protective layer on a surface of the color filter layer, wherein the black matrix is located between two neighboring color filter layers;
S20, depositing a cathode auxiliary wiring layer on a surface of the protective layer, and defining a cathode auxiliary wiring region by lithography to obtain a color film substrate;
S30, providing a second glass substrate, forming a thin-film transistor (TFT) layer on the second glass substrate, depositing an anode metal layer on the TFT layer, coating an organic photoresist on the anode metal layer to form a pixel defining layer, and sequentially preparing an OLED light-emitting layer and a cathode metal layer on a surface of the pixel defining layer and a surface of the anode metal layer to obtain an array substrate; and
S40, encapsulating the array substrate and the color film substrate, contacting the cathode auxiliary wiring layer with the cathode metal layer, and finally forming the OLED display panel.

10. The manufacturing method of the OLED display panel as claimed in claim 9, wherein in the step S10, the color filter layer comprises a red resist, a green resist, and a blue resist, the black matrix is disposed between any two of the red resist, the green resist, and the blue resist, and the black matrix is disposed opposite to the pixel defining layer.

11. The manufacturing method of the OLED display panel as claimed in claim 9, wherein in the step S20, a thickness of the cathode auxiliary wiring layer ranges from 300 to 5000 Å.

12. The manufacturing method of the OLED display panel as claimed in claim 9, wherein in the step S20, a material of the cathode auxiliary wiring layer is selected from the group consisting of indium tin oxide (ITO), indium zinc oxide (IZO), and silver-magnesium alloy.

13. The manufacturing method of the OLED display panel as claimed in claim 9, wherein in the step S20, the cathode auxiliary wiring layer comprises laminated an ITO layer, a silver metal layer, and an ITO layer.
